(19) United States
(12) Patent Application Publication
(10) Pub. No.: US 2011/0052809 A1
(43) Pub. Date: Mar. 3, 2011

(54) METHOD FOR APPLICATION OF AN ADHESION PROMOTER COMPOSITION TO A SUBSTRATE

(75) Inventors: Wolf-Rüdiger Huck, Gockhausen (CH); Remo Nufer, Effretikon (CH)

(73) Assignee: SIKA TECHNOLOGY AG, BAAR (CH)

(21) Appl. No.: 12/937,500

(22) PCT Filed: Apr. 9, 2009
(86) PCT No.: PCT/EP09/54279

§ 371 Date: Nov. 12, 2010

(30) Foreign Application Priority Data
Apr. 11, 2008 (EP) 08154412.4

(51) Int. Cl. C23C 16/448

(52) U.S. Cl. 427/255.25; 118/715; 118/724

(57) ABSTRACT

The present invention relates to a method for application of an adhesion promoter composition, containing at least one adhesion promoter substance, to a substrate. For this purpose, the adhesion promoter substance is vaporized and the vapor formed is transported to the substrate via a carrier gas.

### BACKGROUND

The invention relates to the field of application technology, for application of an adhesion promoter composition to a substrate.

Adhesion promoter compositions are conventionally used to improve adhesion of materials, in particular adhesives and sealants, to a substrate. Thus, for example, silane and titanate compounds that are used as “primer activators” or “adhesive activators” for pretreatment of surfaces to be bonded or sealed are known to the person skilled in the art.

Various methods have been proposed for application of an adhesion promoter composition to a substrate.

Thus, for example, according to WO 2006/005606, an adhesion promoter is applied to the respective workpieces using a roller, spray, or dip method.

The aforementioned methods have the disadvantage that it is difficult to dispense the amounts of adhesion promoter composition to be applied. Moreover, for higher viscosity adhesion promoter compositions, the range of application of these methods is considerably reduced since, for example, when applying them to a rough surface, the adhesion promoter composition does not completely penetrate into the pores and therefore the surface is not completely wetted.

For economic reasons and also in order to achieve optimal adhesion, it is furthermore often desirable to apply only small amounts of an adhesion promoter composition to the substrate. This can be achieved with the indicated methods only if the adhesion promoter composition to be applied is diluted, preferably with a volatile solvent. However, the use of evaporating solvents is often disadvantageous because of the general conditions and additional equipment required for industrial hygiene and occupational safety reasons.

This problem is especially acute in the enclosed production facilities where adhesion promoter compositions are typically applied.

The indicated problems are why WO2007/132013 proposes using an ultrasonic sprayer to apply an adhesion promoter composition to a substrate surface. A disadvantage of this method is that such an application requires relatively sophisticated application equipment.

### SUMMARY

The aim of the present invention is therefore to provide a simple and safe method making it possible to uniformly apply even small amounts of an adhesion promoter composition to a substrate.

Since evaporation of the solvent is no longer necessary, an adhesive or sealant can furthermore be applied immediately after application of the adhesion promoter substance.

The aim is achieved according to the invention by means of the method according to the present disclosure.

A further aspect of the invention relates to a device according to the present disclosure.

### BRIEF DESCRIPTION OF THE DRAWING

FIG. 1 is an illustration of a device for carrying out methods of the present disclosure.

### DETAILED DESCRIPTION OF EMBODIMENTS

The invention relates to a method for application of an adhesion promoter composition, containing at least one adhesion promoter substance, to a substrate, wherein the adhesion promoter substance is vaporized and the vapor formed is transported via a carrier gas to the substrate.

Typically used adhesion promoter substances generally have a boiling point at normal pressure that is above the decomposition temperature. But because of the vapor pressure of the liquid adhesion promoter substance, at even relatively low temperatures lying below the decomposition temperature and therefore also below the boiling point of the adhesion promoter substance, an equilibrium sets in between the liquid phase and the gas phase, where the adhesion promoter substance goes from the liquid phase to the gas phase. Since the adhesion promoter substance present in the gas phase is continuously leaving this equilibrium via the carrier gas, continuous transfer of the adhesion promoter substance from the liquid phase to the gas phase is ensured even at temperatures below the boiling point. Thus because of this steady “evaporation”, the adhesion promoter substance is continuously transported to the substrate, which is exposed to the carrier gas. Surprisingly, a relatively brief exposure of the substrate is sufficient to apply enough adhesion promoter substance per substrate surface area to provide the desired adhesion promotion.

The method according to the invention thus makes it possible to uniformly apply even small amounts of the adhesion promoter composition or the adhesion promoter substance contained in the latter when either a greatly reduced amount of solvent or even no solvent at all is present. According to a preferred embodiment, the adhesion promoter substance is essentially free of solvent, i.e., solvent is present as at most 5 wt. %, in particular at most 1 wt. %, preferably at most 0.5 wt. %. Since the user applying the adhesion promoter composition is not exposed to any volatile solvents at all, safer working conditions are ensured. The limits imposed by VOC regulations can therefore be completely avoided. Moreover, because of the elimination of the evaporation time, the treated substrate can be further processed immediately after application of the adhesion promoter composition. Therefore an adhesive or sealant can be applied immediately after application of the adhesion promoter substance. For example, this can be done using an application robot which simultaneously has on its arm a device for application of the adhesion promoter composition or the adhesion promoter substance as well as a device for application of an adhesive or sealant. Consequently, only one robot station is necessary and hence less space is needed, and also the time required for the cycle can be shortened.

A further advantage of the method according to the invention is that the adhesion promoter substance can be transported to the substrate under mild and therefore quite controllable conditions. It thus differs fundamentally from, for example, the method known from EP-A-1388470, according to which adhesion promoting compounds are added to a reactive plasma.

Moreover, the method according to the invention makes it possible to selectively apply the adhesion promoter substance or the adhesion promoter composition containing the latter to a specified region of the substrate surface. Thus application of the adhesion promoter composition can be limited to the regions brought into contact with the adhesive or sealant, which is especially an advantage with regard to consumption of the adhesion promoter substance and the esthetic appearance of the bonded or sealed substrate.

The vaporization temperature, the carrier gas flow rate, the contact surface area between the adhesion promoter substance in the liquid phase and the carrier gas, and/or the exposure time of the substrate, for example, can accordingly be varied, depending on the adhesion promoter substance, in order to adjust the desired amount of adhesion promoter substance in the adhesion promoter composition applied to the substrate

Hydrolyzable adhesion promoter substances, for example, are especially suitable adhesion promoter substances for the method according to the invention.

The at least one hydrolyzable adhesion promoter substance can be an organosilicon compound. In principle, all organosilicon compounds known to the person skilled in the art that are used as adhesion promoters are suitable. Preferably this organosilicon compound has at least one, preferably three alkoxy groups directly bonded to a silicon atom through an oxygen-silicon bond. In addition, the organosilicon compound has at least one substituent which is bonded to the silicon atom through a silicon-carbon bond, and which optionally has a functional group selected from the group consisting of oxirane, hydroxy, (meth)acryloxy, amino, mercapto, vinyl, and nitrile groups.

Organosilicon compounds of formula (I) or formula (II) or formula (III) are especially suitable as the organosilicon compounds.

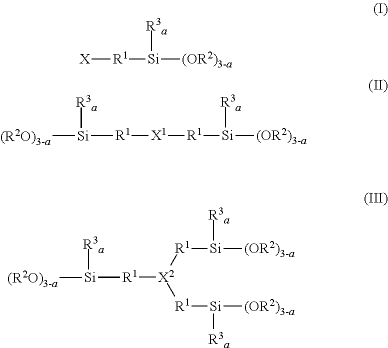

Here the R¹ stands for a linear or branched, optionally cyclic alkylene group with 1 to 20 C atoms, optionally with aromatic moieties and optionally with one or more heteroatoms, in particular nitrogen atoms.

R² stands for an alkyl group with 1 to 5 C atoms, in particular for a methyl or ethyl group, or an acyl group.

R³ stands for an alkyl group with 1 to 8 C atoms, in particular a methyl group.

X stands for H or a functional group which is selected from the group consisting of an oxirane group, an OH group, a (meth)acryloxy group, an amino group, an SH group, an acylthio group, and a vinyl group, preferably for an amino group. For the sake of completeness we mention that in this document, acylthio is understood to mean the substituent

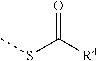

where R⁴ stands for an alkyl, in particular an alkyl with 1 to 20 carbon atoms, and the dashed line represents the bond with substituent R¹,

X¹ stands for a functional group selected from the group consisting of NH, S, S₂, and S₄.

X² stands for a functional group selected from the group consisting of N and an isocyanurate group, and a stands for a value of 0, 1, or 2, preferably 0.

The substituent R¹ means in particular a methylene, propylene, methylpropylene, butylene, or dimethylbutylene group. A propylene group is especially preferred as substituent R¹.

Organosilicon compounds having amino, mercapto, or oxirane groups are also called “aminosilanes,” “mercaptosilanes,” or “epoxysilanes,” “Polyaminosilane” is understood to mean silicon compounds which have more than one amino group. “Polysilane” is understood to mean silicon compounds which have more than one silane group. Here “silane group” is understood to mean the group of formula (I′).

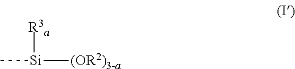

The residue R² and the subscript a are defined above.

Suitable organosilicon compounds of Formula (I) include, for example, organosilicon compounds selected from the group consisting of octyltrimethoxysilane, dodecyltrimethoxysilane, hexadecyltrimethoxysilane, methyloctyldimethoxysilane;
3-glycidyloxypropyltrimethoxysilane, 3-glycidyloxypropyltriethoxysilane;
3-methacryloxypropyltrialkoxysilane, 3-methacryloxypropyltriethoxysilane, 3-methacryloxypropyltrimethoxysilane;
3-aminopropyltrimethoxysilane, 3-aminopropyltriethoxysilane, 3-aminopropyldimethoxymethylsilane, 3-amino-2-methylpropyltrimethoxysilane, N-(2-aminoethyl)-3-aminopropyltrimethoxysilane, N-(2-aminoethyl)-3-aminopropyltriethoxysilane, N-(2-aminoethyl)-3-aminopropyldimethoxymethylsilane, 4-aminobutyltrimethoxysilane, 4-aminobutyldimethoxymethylsilane, 4-amino-3-methylbutyltrimethoxysilane, 4-amino-3,3-dimethylbutyltrimethoxysilane, 4-amino-3,3-dimethylbutyldimethoxymethylsilane, 2-aminoethyldimethoxymethylsilane, aminomethyltrimethoxysilane, aminomethyldimethoxymethylsilane, aminomethylmethoxydimethylsilane, 7-amino-4-oxaheptyldimethoxymethylsilane, N-(methyl)-3-aminopropyltrimethoxysilane, N-(n-butyl)-3-aminopropyltrimethoxysilane;
3-mercaptopropyltriethoxysilane, 3-mercaptopropyltrimethoxysilane, 3-mercaptopropylmethyldimethoxysilane;
3-acylthiopropyltrimethoxysilane;
vinyltrimethoxysilane and vinyltriethoxysilane.

Also preferred are the just mentioned organosilicon compounds whose alkoxy groups are replaced by acetoxy groups, such as, for example, octyltriacetoxysilane (octyl-Si(O(O═C)CH₃)₃). Such organosilicon compounds cleave acetic acid in hydrolysis.

Preferred among the mentioned organosilicon compounds are those which have an organic substituent bonded to the silicon atom, which additionally have another functional group, i.e., which is not an alkyl group, and correspond to Formula (I), in which X is not H.

For example, suitable organosilicon compounds of formula (II) include the organosilicon compounds selected from the group consisting of bis[3-(trimethoxysilyl)propyl]amine, bis[3-(triethoxysilyl)propyl]amine, 4,4,15,15-tetraethoxy-3,16-dioxa-8,9,10,11-tetrathia-4,15-disilaoctadecane (bis(triethoxysilylpropyl)polysulfide [or] bis(triethoxysilylpropyl)tetrasulfane) and bis(triethoxysilylpropyl)disulfide.

Suitable organosilicon compounds of formula (III) are, for example, organosilicon compounds selected from the group consisting of tris[3-(trimethoxysilyl)propyl]amine, tris[3-(triethoxysilyl)propyl]amine, 1,3,5-tris[3-(trimethoxysilyl)propyl]-1,3,5-triazine-2,4,6(1H,3H,5H)-trione urea (=tris(3-(trimethoxysilyl)propyl)isocyanurate), and 1,3,5-tris[3-(triethoxysilyl)propyl]-1,3,5-triazine-2,4,6(1H,3H,5H)-trione urea (=tris(3-(triethoxysilyl)propyl)isocyanurate).

The adhesion promoter composition preferably does not contain any alkylsilanes, i.e., preferably H is different from H [sic].

Aminosilanes are preferred as the organosilicon compounds, in particular aminosilanes with X═NH₂ or NH₂—CH₂—CH₂—NH, X¹═NH and X²═N. Especially preferred are 3-aminopropyltrimethoxysilane, N-(2-aminoethyl)-3-aminopropyltrimethoxysilane, bis[3-(trimethoxysilyl)propyl]amine, 3-aminopropyltriethoxysilane, N-(2-aminoethyl)-3-aminopropyltriethoxysilane, and bis[3-(triethoxysilyl)propyl]amine as well as mixtures thereof.

The at least one hydrolyzable adhesion promoter substance can additionally be an organotitanium compound. In principle, all organotitanium compounds known to the person skilled in the art that are used as adhesion promoters are suitable.

A particularly suitable organotitanium compound is one having at least one functional group which is selected from the group consisting of an alkoxy group, sulfonate group, carboxylate group, dialkylphosphate group, dialkylpyrophosphate group, and acetylacetonate group, or mixtures thereof, and which is bonded directly to a titanium atom through an oxygen-titanium bond.

Especially suitable compounds are those in which all the substituents bonded to the titanium are selected from the group consisting of an alkoxy group, sulfonate group, carboxylate group, dialkylphosphate group, dialkylpyrophosphate group, and acetylacetonate group, where all substituents can be the same or different from each other.

As the alkoxy groups, in particular “neoalkoxy” substituents have proven to be especially suitable, in particular those of the following formula (IV):

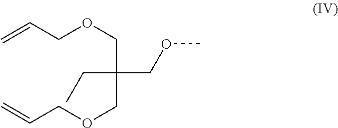

As the sulfonic acids, aromatic sulfonic acids have proven to be especially suitable in which the aromatics are substituted with an alkyl group. Residues of the following formula (V) are considered as preferred sulfonic acids.

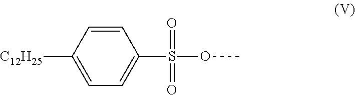

Carboxylates of fatty acids have proven to be especially suitable as the carboxylate groups. Decanoate is a preferred carboxylate.

In the above formulas (IV) and (V), here the dashed bond indicates the oxygen-titanium bond.

Organotitanium compounds are commercially available, for example from Kenrich Petrochemicals or DuPont. Examples of suitable organotitanium compounds are, for example, KEN REACT® KR TTS, KR 7, KR 9S, KR 12, KR 26S, KR 33DS, KR 38S, KR 39DS, KR44, KR 134S, KR 138S, KR 158FS, KR212, KR 238S, KR 262ES, KR 138D, KR 158D, KR238T, KR 238M, KR238A, KR238J, KR262A, LICA 38J, KR 55, LICA 01, LICA 09, LICA 12, LICA 38, LICA 44, LICA 97, LICA 99, KR OPPR, KR OPP2 from Kenrich Petrochemicals or TYZOR® ET, TPT, NPT, B™, AA, AA-75, AA-95, AA-105, TE, ETAM, OGT from DuPont. KEN REACT® KR 7, KR 9S, KR 12, KR 26S, KR 38S, KR44, LICA 09, LICA 44, NZ 44, as well as TYZOR® ET, TPT, NPT, B™, AA, AA-75, AA-95, AA-105, TE, ETAM from DuPont are preferred.

Especially preferred organotitanium compounds are those with substituents of formula (IV) and/or (V) bonded to the titanium atom through an oxygen-titanium bond.

The at least one hydrolyzable adhesion promoter substance can additionally be an organozirconium compound. In principle, all organozirconium compounds known to the person skilled in the art that are used as adhesion promoters are suitable. An especially suitable organozirconium compound in one having at least one functional group which is selected from the group consisting of an alkoxy group, sulfonate group, carboxylate group, and phosphate group, or mixtures thereof, and which is bonded directly to a zirconium atom through an oxygen-zirconium bond.

Isopropoxy and “neoalkoxy” substituents, in particular of formula (IV) as described above, have proven to be especially suitable as the alkoxy groups, where here the dashed bond indicates the oxygen-zirconium bond.

As the sulfonic acids, aromatic sulfonic acids have proven to be especially suitable in which the aromatics are substituted with an alkyl group. Preferred sulfonic acids can be residues of the following [sic] formula (V) as described above, where here the dashed bond indicates the oxygen-zirconium bond.

Carboxylates of fatty acids have proven to be especially suitable as the carboxylate groups. Stearates and isostearates are considered as preferred carboxylates.

Organozirconium compounds are commercially available, for example from Kenrich Petrochemicals. Examples of suitable organozirconium compounds are, for example, KEN REACT® NZ 38J, NZ TPPJ, KZ OPPR, KZ TPP, NZ 01, NZ 09, NZ 12, NZ38, NZ 44, NZ 97.

Furthermore, the adhesion promoter substance of the composition according to the invention can contain mixtures of at least one organosilicon compound with at least one organotitanium compound and/or with at least one organozirconium compound. Mixtures of at least one organotitanium compound with at least one organozirconium compound are also possible. Mixtures of at least one organosilicon compound with at least one organotitanium compound are preferred.

Mixtures of several organosilicon compounds or mixtures of an organosilicon compound with an organotitanium compound or an organozirconium compound are especially preferred.

Mixtures of aminosilane(s) and mercaptosilane(s) are especially preferred.

Mixtures of at least one polyaminosilane [and] at least one polysilane, in particular at least one disilane, and at least one mercaptosilane have been shown to be especially advantageous.

Such a mixture is in particular a mixture of:

A: a polyaminosilane, preferably N-(2-aminoethyl)-3-aminopropyltrimethoxysilane,

B: a polysilane, preferably bis(3-trimethoxysilylpropyl)amine, and

C: a mercaptosilane, preferably 3-mercaptopropyltrimethoxysilane,

where the weight ratio of A:B:C is in particular X:Y:Z, with the value of X from 0.1 to 10, Y from 0.1 to 10, and Z from 0.1 to 10.

According to the method of the present invention, the adhesion promoter substance can be heated in order to accelerate its vaporization. In the method according to the invention, if an organosilicon compound, an organotitanium compound, or an organozirconium compound is used as an adhesion promoter substance, then preferably the vaporization temperature is adjusted to 100° C. to 250° C. Therefore this lies well below the decomposition temperature of the adhesion promoter substance.

In connection with the present invention, the term “carrier gas” is understood to mean an gas that is inert relative to the adhesion promoter substance. For example, nitrogen, oxygen, air, and/or a noble gas can be used as preferred carrier gases. In particular when organosilicon compounds, organotitanium compounds, or organozirconium compounds are used, another component can also be added to the carrier gas for hydrolysis of the aforementioned compound. For example, if air is used, then the air can additionally contain a certain amount of moisture, in particular water. The air humidity at 20° C. is preferably between 20% and 70% for this purpose. The amount of water is preferably calculated so that the adhesion promoter substance can be hydrolyzed or partially hydrolyzed by the time it hits the substrate.

It is also conceivable to heat the carrier gas in order to thereby indirectly heat the adhesion promoter substance and accelerate its vaporization.

Although it is an advantage of the present invention that uniform and sufficient wetting of the substrate surface is achieved even in the absence of a solvent, the present invention also includes methods in which the adhesion promoter substance is supplied dissolved in a solvent.

Suitable solvents are in particular volatile solvents, i.e., solvents with a boiling point at 760 torr between 25° C. and 140° C., in particular between 50° C. and 120° C., preferably between 65° C. and 99° C.

In addition, less volatile solvents are also suitable, i.e., solvents having a boiling point at 760 ton above the baking temperature. In particular, they have a boiling point≧100° C., preferably between 100° C. and 200° C., preferably between 140° C. and 200° C.

Furthermore, it has been shown that mixtures of different solvents can be used in particular. For example, mixtures of hydrocarbons or mixtures of at least one hydrocarbon with at least one polar solvent having at least one heteroatom in its structural formula can be used. The hydrocarbon can be saturated, or olefinic or aromatic unsaturated. The hydrocarbon is preferably saturated. O, N, and S in particular are considered suitable as a heteroatom in the polar solvent. It is preferred for the at least one heteroatom in the structural formula of the polar solvent to be an oxygen atom, which is especially preferred in the form of hydroxyl, carbonyl, ether, carboxylic acid, or carboxylic derivative groups such as, for example, an ester, amide, or carboxylate group. Preferred polar solvents are water, alcohols, and ketones. The most preferred polar solvents are alcohols, in particular saturated, branched, or linear or cyclic alcohols with 1 to 8 carbon atoms.

Preferred solvents are alcohols and aliphatic and cycloaliphatic hydrocarbons, in particular ethanol, isopropanol, hexane, cyclohexane, heptane, or octane, as well as mixtures thereof. The solvent is preferably ethanol or heptane.

Solvent mixtures of an alcohol and an aliphatic or cycloaliphatic hydrocarbon are considered as especially preferred, in particular such mixtures of ethanol or isopropanol with hexane or cyclohexane or heptane or octane, as well as mixtures thereof. The mixture of ethanol and heptane has been shown to be an especially preferred solvent mixture.

Less volatile solvents include in particular hydrocarbons such as toluene, xylene, or a hydrocarbon mixture with boiling point between 120° C. and 200° C., in particular between 120° C. and 140° C.

The adhesion promoter composition applied to the substrate can consist of the adhesion promoter substance or can include at least one other constituent. The proportion of adhesion promoter substance is preferably 90 wt. %, in particular 95 wt. %, preferably 99 wt. %, calculated on the basis of the adhesion promoter composition.

The at least one other constituent can, depending on the suitability, be applied in the same way as the adhesion promoter substance or else by a conventional method suitable for the purpose.

Catalysts for hydrolysis, for example for hydrolysis of silane groups, can also be used as a constituent of the adhesion promoter composition, and namely for example in the form of organic carboxylic acids such as benzoic acid or salicylic acid, organic carboxylic acid anhydrides such as phthalic anhydride or hexahydrophthalic anhydride, silyl esters of organic carboxylic acids, organic sulfonic acids such as p-toluenesulfonic acid or 4-dodecylbenzenesulfonic acid or methylsulfonic acid, or other organic or inorganic acids, or mixtures of the aforementioned acids; as well as catalysts for reaction of isocyanate groups, for example, tin compounds such as tin(II) octoate, monobutyltin trichloride, dibutyltin dichloride, dibutyltin oxide, dibutyltin diacetate, dibutyltin dilaurate, dibutyltin diacetylacetonate, dibutyltin dicarboxylates, dioctyltin dicarboxylates, alkyltin thioesters, bismuth compounds such as bismuth(III) octoate, bismuth(III) neodecanoate, zinc compounds such as zinc(II) octoate, as well as compounds containing amino groups such as, for example, 2,2′-dimorpholinodiethyl ether, 1,4-diazabicyclo[2.2.2]octane, 1,8-diazabicyclo[5.4.0]undec-7-ene; as well as other catalysts such as titanates and zirconates.

Furthermore, the usual wetting agents and additives employed in primer chemistry can be used.

UV absorbers and optical brighteners are also suitable as additional constituents. Such optical brighteners absorb UV light and emit visible (typically blue) light. A preferred optical brightener is Ciba UVITEX® OB from Ciba Specialty Chemicals. Additional suitable optical brighteners are given, for example, in Kirk-Othmer, Encyclopedia of Chemical Technology, 4th Ed., John Wiley & Sons, New York, Vol. 11, pp. 227-241. For example, the UV absorbers can be organic, such as for example from the TINUVIN® product line of Ciba Specialty Chemicals.

The adhesion promoter composition can be applied to the surface of quite diverse substrates. Especially suitable substrates are inorganic substrates such as glass, glass ceramic, concrete, mortar, brick, tile, plaster, and natural stones such as granite or marble; metals or alloys such as aluminum, steel, nonferrous metals, galvanized metals; organic substrates such as wood, particleboard, plastics such as PVC, polycarbonates, PMMA, polyesters, epoxy resins; coated substrates such as powder-coated metals or alloys; as well as paints and lacquers, in particular automotive topcoats. The most preferred substrates are glass, in particular ceramic-coated glass, lacquered substrates such as lacquered metal flanges, as well as plastics, in particular PVC.

The present invention can be used for pretreatment of substrate surfaces which are to be subsequently bonded using an adhesive or a sealant. As pretreatment, preferably an adhesion promoter substance is applied by means of the method described above. Therefore suitable applications, for example, are bonding components used in civil engineering and in manufacture or repair of industrial goods or consumer goods, in particular windows, household appliances or means of transport such as water or land vehicles, preferably automobiles, busses, freight vehicles, trains, or ships; sealing joints, seams, or cavities in industrial manufacture or repair, or in civil engineering. The present invention is especially suitable for application of an adhesion promoter composition to a pane, preferably a glass pane, where the pane is to be bonded, in particular adhesively bonded to at least one other substrate made of glass, wood, lacquer, or plastic, in particular polyvinyl chloride (PVC). Therefore the method according to the invention can be preferably used in automotive assembly, where glass is bonded to a lacquer-coated auto body, or in door or window assembly, where glass is bonded to a wooden or plastic frame.

The present invention furthermore relates to a method for bonding and/or sealing at least two substrate surfaces S1 with a substrate S2, including the steps: (i) applying an adhesion promoter composition by means of the method described above to a substrate S1 and/or a substrate S2; (ii) applying an adhesive or sealant to at least one substrate surface S1 and/or S2 or between substrates S1 and S2; (iii) bringing substrates S1 and S2 into contact via the applied adhesive or sealant; and (iv) curing the applied adhesive or sealant; where substrates S1 and S2 are the same or different from each other.

When used as a sealant, the composition is applied between substrates S1 and S2 and then it is cured. Usually the sealant is pressed into a joint.

The adhesive or sealant is preferably applied uniformly.

In both applications, substrate S1 can be the same as or different from substrate S2.

Suitable substrates S1 or S2 are, for example, inorganic substrates such as glass, glass ceramic, concrete, mortar, brick, tile, plaster, and natural stones such as granite or marble; metals or alloys such as aluminum, steel, nonferrous metals, galvanized metals; organic substrates such as wood, plastics such as PVC, polycarbonates, PMMA, polyesters, epoxy resins; coated substrates such as powder-coated metals or alloys; as well as paints and lacquers, in particular automotive topcoats.

It has been shown that polyurethane adhesives, (meth)acrylate adhesives, epoxy resin adhesives, or adhesives based on prepolymers with alkoxysilane functional groups are best suited for bonding.

Suitable polyurethane adhesives are firstly one-component moisture-curing adhesives or two-component polyurethane adhesives. Such adhesives contain polyisocyanates, in particular in the form of prepolymers containing isocyanate groups. Preferred polyurethane adhesives are those such as are commercially available from Sika Schweiz AG in the SIKAFLEX®, SIKAPOWER®, and SIKAFORCE® product lines.

(Meth)acrylate adhesives are understood to mean two-component adhesives for which the first component includes acrylic acid and/or methacrylic acid and/or their esters, and the second component includes a radical former, in particular a peroxide. Such adhesives as are commercially available in the SIKAFAST® product line from Sika Schweiz AG are preferred.

Epoxy resin adhesives are understood to mean adhesives which are formulated on the basis of glycidyl ethers, in particular diglycidyl ethers of bisphenol A and/or bisphenol F. Especially suitable are two-component epoxy resin adhesives for which one component contains diglycidyl ethers of bisphenol A and/or bisphenol F and the second component contains polyamines and/or polymercaptans. Preferred two-component epoxy resin adhesives are those such as are commercially available in the SIKADUR® product line from Sika Schweiz AG.

The two-component epoxy resin adhesives SIKADUR®-COMBIFLEX®, SIKADUR®-31, SIKADUR®-31DW, AND SIKADUR®-33, PREFERABLY SIKADUR®-COMBIFLEX®, from Sika Schweiz AG have been shown to be especially suitable for bonding films.

Adhesives based on prepolymers containing alkoxysilane functional groups are understood to mean in particular adhesives based on MS polymers or SPUR (silane-terminated polyurethane) prepolymers. Such alkoxysilane-functional prepolymers can be synthesized, for example, via a hydrosilylation reaction between polyethers having at least two C═C double bonds, in particular allyl-terminated polyoxyalkylene polymers, and a hydrosilane, or via an addition reaction between isocyanatoalkylalkoxysilanes and polyols or hydroxy-functional polyurethane prepolymers, or via an addition reaction between aminoalkylalkoxysilanes and isocyanate-functional polyurethane prepolymers, where the polyurethane prepolymers themselves can be obtained via reaction of polyisocyanates and polyols and/or polyamines by a method known in the prior art. Adhesives based on alkoxysilane-functional prepolymers are moisture-curing and react at room temperature.

In principle, reactive hot melt adhesives can also be used, such as are commercially available from Sika Schweiz AG in the SIKAMELT® product line. However, room temperature-curing adhesives are preferred.

Before application of the adhesive or sealant, the substrates can be pretreated as needed in addition to application of the adhesion promoter composition. Such pretreatments include in particular physical and/or chemical cleaning methods, for example grinding, sand blasting, brushing, or the like, or treatment with cleaning agents or solvents.

After bonding or sealing substrates S1 and S2, a bonded or sealed article is obtained. Such an article can be a structure, in particular a civil engineering structure, or a means of transport.

The article is preferably a means of transport, for example a water or land vehicle, in particular an automobile, a bus, a freight vehicle, a train, or a ship, or a mounted part thereon. The bonded or sealed article is especially preferably a means of transport, in particular an automobile, or a mounted part on a means of transport, in particular on an automobile.

The present invention further relates to a device for carrying out the above-described method, including a block with a carrier gas channel running through the block, and a means for feeding the adhesion promoter substance into the carrier gas channel. The block includes a first surface section having a carrier gas inlet and defining an inlet side, and a second surface section having a carrier gas outlet and defining an outlet side. The block can have any shape suitable for the purpose, for example the shape of a rectangular parallelepiped or a cylinder.

The carrier gas channel runs through the block from the carrier gas inlet to the carrier gas outlet. In principle, the carrier gas channel can have any design of the cross section and course suitable for the purpose. In a rectangular or cylindrical block for which the inlet side is perpendicular to the outlet side, it is conceivable, for example, that the carrier gas channel runs through the block directly (and thus diagonally) or in two mutually perpendicular carrier gas channel sections.

In general, the carrier gas inlet is joined to a means for connecting to a carrier gas feed, for example an inlet port. In addition, the carrier gas outlet can be joined to a means for targeted application of the adhesion promoter substance, for example, a section of tubing projecting from the block, in particular a nozzle or bell. It is conceivable, for example, that a hose is disposed between the nozzle and the carrier gas outlet. Because of its flexibility, this hose makes it possible to aim the nozzle as desired without needing to move the block.

Thus the method can be carried out on a stationary substrate by moving the nozzle over the substrate to be treated, for example by using a robot, which in practice is very advantageous.

Moreover, the device has a means for feeding the adhesion promoter substance into the carrier gas channel. This means generally runs through an adhesion promoter substance channel leading into the carrier gas channel, which in general is closed off by a septum.

The carrier gas channel is preferably designed to ensure the best possible contact between the adhesion promoter substance and the carrier gas. For this purpose, a means can be provided in the carrier gas channel that is intended to be wetted with the adhesion promoter substance and to consequently ensure the largest possible adhesion promoter substance surface area. In addition, in order to ensure the best possible contact between the carrier gas and the adhesion promoter substance, the means in the carrier gas channel is designed to introduce turbulences into the gas stream flowing through the carrier gas channel.

According to a further preferred embodiment, a means for heating the block is also attached to the device. All means known to the person skilled in the art can be used for this purpose. It is conceivable, for example, that the block is placed on a heating plate or that a heating coil is included as an integral component. In addition, the heating can be done without any direct contact with the block, for example by induction. In order to ensure good heat transfer from the block to the adhesion promoter substance, the block is preferably made from a material with a high thermal conductivity coefficient, for example aluminum.

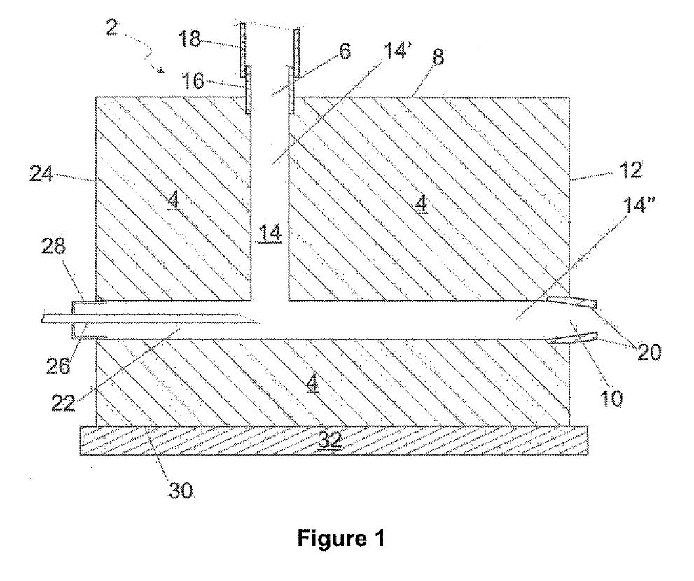

A purely schematic cross-sectional view of an embodiment of the described device is shown in the attached FIG. 1.

According to FIG. 1, device 2 includes rectangular block 4 with top surface 8 having carrier gas inlet 5 and defining an inlet side, and outlet side 10 that is perpendicular to the inlet side and has carrier gas outlet 12. Carrier gas channel 14 runs through block 4 from carrier gas inlet 6 to carrier gas outlet 10.

Carrier gas channel 14 on the inlet side has a first carrier gas channel section 14′, running essentially vertically, and on the outlet side has a second carrier gas channel section 14″, running essentially horizontally. Carrier gas inlet 6 is flow-coupled with inlet port 16 for connection of carrier gas feed 18, while carrier gas outlet 10 is flow-coupled with nozzle 20, projecting out essentially perpendicularly from outlet side 12.

The block furthermore includes adhesion promoter substance channel 22. This channel leads from side 24 of block 4, opposite outlet side 12, into carrier gas channel 14. Adhesion promoter substance channel 22 runs in the extension of the second carrier gas section 14″, so that carrier gas channel 14 plus adhesion promoter substance channel 22 in profile essentially form an inverted T shape.

The device in addition has a means for introducing the adhesion promoter substance into carrier gas channel 14. According to FIG. 1, this means is in the form of a small tube 26 running through substance promoter substance channel 22. Adhesion promoter substance channel 22 is then closed off by means of septum 28.

In order to ensure the largest possible surface area for the adhesion promoter substance introduced into carrier gas channel 14 and thus to ensure the largest possible contact surface area between the adhesion promoter substance and the carrier gas, for example glass wool (not shown), which is wetted with the adhesion promoter substance, is inserted into the second carrier gas channel section 14″. The glass wool moreover has the effect of introducing turbulences into the carrier gas stream, which additionally improves contact between the carrier gas and the adhesion promoter substance.

Bottom surface 30 of block 4 lies on heating plate 32, which is intended to heat block 4 and thus to heat the adhesion promoter substance introduced into carrier gas channel 14.

The carrier gas, through carrier gas feed 18 and inlet port 16 connected to the feed, is fed into carrier gas channel 14 of block 4 heated by heating plate 32, and the adhesion promoter substance is introduced by means of tube 26 through adhesion promoter substance channel 22 into carrier gas channel 14 and vaporized. The vapor of the adhesion promoter substance generated is transported via the carrier gas toward outlet side 12, and is applied to a substrate through nozzle 20.

Besides the course of the carrier gas channel shown in FIG. 1, it is also conceivable in particular that the carrier gas channel runs diagonally downward from the inlet side to the outlet side. This can especially be an advantage if there is a temperature gradient in the block that increases as the distance from the heating plate decreases. Since in such an embodiment the liquid adhesion promoter substance continuously flows downward in the carrier gas channel, its vapor pressure continuously rises in the direction toward the carrier gas outlet, and thus in the direction of increasing concentration of the gas-phase adhesion promoter substance.

In addition, it is conceivable that there is a recess in the carrier gas channel that functions as a sink for the adhesion promoter substance. This also is preferably designed so that the surface area of the adhesion promoter substance and thus the contact surface area between the carrier gas and the adhesion promoter substance is as large as possible.

An exemplary embodiment using the device shown in FIG. 1 is elaborated below. Of course, the invention is not limited to the exemplary embodiment shown and described. It is understood that the above-indicated features of the invention can be used not only in the combination given in each case, but also in other modifications, combinations, and alterations or in isolation, without going beyond the scope of the invention.

### EXAMPLES

### Application of an Adhesion Promoter Composition to a Substrate

An aluminum block shown in FIG. 1 with height of about 15 cm was heated to 150° C. Nitrogen gas was fed at a gas flow rate of 1.5 to 2 L/min through a carrier gas channel running through the block with cross-sectional area of about 12.5 mm². At time t₁₀ₛ), or t₁ₘᵢₙ or t₄ₘᵢₙ 10 seconds or 1 minute or 4 minutes after injection (spray, stainless steel tube) of composition 1 or 2 according to Table 1 into the carrier gas channel, a test flat glass substrate (tin side) was positioned at a specified distance away from the carrier gas outlet or from the nozzle connected to the outlet and was moved sideways relative to the direction of the outgoing stream.

The vapor of the adhesion promoter substance entrained with the carrier gas was deposited on the glass, where the glass was moved at a speed of 10 cm/second and at a distance of about 5 to 6 μm alongside the carrier gas outlet or the nozzle.

Then after a waiting period of 10 minutes, a commercially available one-component moisture-curing polyurethane adhesive (SIKAFLEX® 250-DM-2, available from Sika Schweiz AG) was applied cold (25° C.),

TABLE 1
Adhesion promoter compositions. Data given in parts by weight.

| | 1 | 2 |
|---|---|---|
| N-(2-aminoethyl)-3-aminopropyltrimethoxysilane | 1.5 | 1.5 |
| bis(3-trimethoxysilylpropyl)amine | 1.5 | 1.5 |
| 3-mercaptopropyltrimethoxysilane | 1 | 1 |
| n-butyltitanate | | 1 |

Then the adhesive was cured for 7 days at 23° C. and 50% relative air humidity (storage in a room temperature environmental chamber: EC) and a third of the bead was tested by means of the adhesion test described below. Then the test sample was stored in water for another 7 days at 23° C. (water storage: WS). The adhesion was subsequently tested by the bead test for another third of the bead. Then the substrates were put in poultice storage (100% relative air humidity and 70° C.: PS) and the adhesion of the last third of the bead was subsequently determined.

In the “bead test”, the bead is cut at the end just above the adhesive surface. The cut end of the bead is held with round-tip forceps and pulled from the substrate. This is done by carefully rolling up the bead on the tip of the forceps, and placing a cut perpendicular to the direction in which the bead is pulled, down to the bare substrate. The bead peel rate should be selected so that a cut must be made approximately every 3 seconds. The test distance must be at least 8 cm. The adhesive remaining on the substrate after peeling off the bead is assessed (cohesive failure). The adhesive properties are assessed by estimating the area fraction of cohesive failure on the bonding surface:

1≧95% cohesive failure

2=75%-95% cohesive failure

3=25%-75% cohesive failure

4≦25% cohesive failure

5=0% cohesive failure (purely adhesive failure).

For comparison purposes, a composition consisting of 5 parts composition 1 and 95 parts isopropanol, as well as Sika Aktivator® (available from Sika Schweiz AG), was applied as the adhesion promoter composition in the conventional way by a “wipe on/off” method, as Ref 1 or Ref 2. In the “wipe on/off” method, a wipe (Tela®, Tela-Kimberly Switzerland GmbH) is soaked with the adhesion promoter composition and applied by wiping along the surface of the glass (“wipe on”). Immediately after this application, a dry wipe was run over these spots, whereby excess adhesion promoter composition was removed (“wipe off”). After a waiting period of 10 minutes, the adhesive was applied and tested as described.

Finally as another comparison, as Ref 3, the adhesive was applied on untreated glass and tested as described.

The results obtained are given in Table 2.

TABLE 2
Adhesion results for adhesion promoter compositions applied
in the conventional way and according to the invention.

| | 1 | | | 2 | | | Ref. 1 | | | Ref. 2 | | | Ref. 3 | | |
|---|---|---|---|---|---|---|---|---|---|---|---|---|---|---|---|
| | EC | WS | PS | EC | WS | PS | EC | WS | PS | EC | WS | PS | EC | WS | PS |
| no pretreat | | | | | | | | | | | | | 5 | 5 | 5 |
| conventional | | | | | | | 5 | 3 | 1 | 5 | 4 | 3 | | | |
| t_{10 s} | 3 | 4 | 5 | 2 | 4 | 5 | | | | | | | | | |
| t_{1 min} | 1 | 1 | 4 | 1 | 3 | 4 | | | | | | | | | |
| t_{4 min} | 2 | 2 | 1 | 1 | 1 | 2 | | | | | | | | | |

According to Table 2, with no pretreatment of the substrate (Ref 3), sufficient adhesion was not achieved; all the test samples show 0% cohesive failure. As is also apparent from Table 2, with conventional pretreatment using the “wipe on/off” method, unsatisfactory results were obtained for room temperature storage in an environmental chamber and the test samples stored in water.

In a corresponding measurement series, the temperature of the block was varied for composition 2. The distance was 5-6 cm. The time after injection was 1 minute. The results are given in Table 3.

TABLE 3
Adhesion results for different block temperatures.

| Block temperature | EC | WS | PS |
|---|---|---|---|
| 120° C. | 1 | 4 | 5 |
| 150° C. | 1 | 3 | 4 |

In another measurement series, for a block temperature of 150° C. for composition 2, the distance was varied between the carrier gas outlet, or the nozzle flow-coupled with the outlet, and the substrate.

The time after injection here was 4 minutes. Under the above-indicated conditions, the best results tended to be obtained for composition 2 and a distance of 5-6 cm. The results are summarized in Table 4.

TABLE 4
Adhesion results for different distances.

| Distance | EC | WS | PS |
|---|---|---|---|
| 2-3 cm | 1 | 4 | 4 |
| 5-6 cm | 1 | 1 | 2 |
| 10 cm | 3 | 2 | 1 |

1. A method for applying an adhesion promoter composition comprising at least one adhesion promoter substance to a substrate, the method comprising:
forming a vapor by vaporizing the adhesion promoter substance; and
transporting the vapor to the substrate via a carrier gas.

2. The method of claim 1, wherein the vaporizing is conducted by heating to a temperature below a decomposition temperature of the adhesion promoter substance.

3. The method of claim 1, wherein the adhesion promoter substance is essentially free of solvent.

4. The method of claim 1, wherein the adhesion promoter substance is hydrolyzable.

5. The method of claim 1, wherein the adhesion promoter substance is an organosilicon compound, an organotitanium compound, and/or an organozirconium compound.

6. The method of claim 5, wherein the organosilicon compound is a compound of formula (I) or (II) or (III): 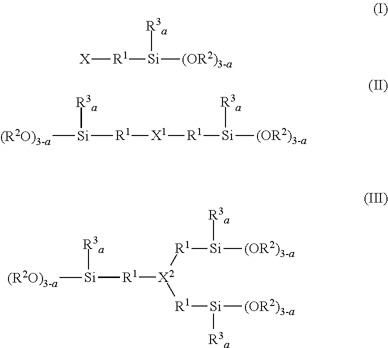
wherein R¹ stands for a linear or branched, optionally cyclic alkylene group with 1 to 20 C atoms, optionally with aromatic moieties and optionally with one or more heteroatoms,
R² stands for an alkyl group with 1 to 5 C atoms, or an acyl group;
R³ stands for an alkyl group with 1 to 8 C atoms, in particular a methyl group,
X stands for H or a functional group selected from the group consisting of an oxirane group, OH group, (meth)acryloxy group, amino group, SH group, acylthio group, and vinyl group,
X¹ stands for a functional group selected from the group consisting of NH, S, S₂, and S₄,
X² stands for a functional group selected from the group consisting of N and an isocyanurate group, and
a stands for one of the values 0, 1, or 2.

7. The method of claim 1, wherein the proportion of the adhesion promoter substance is 90 wt-% calculated on the basis of the weight of the adhesion promoter composition.

8. The method of claim 1, wherein the adhesion promoter composition contains a mixture of:
A: polyaminosilane,
B: polysilane, and
C: mercaptosilane,
and the weight ratio of A:B:C is in particular X:Y:Z, with the value of X from 0.1 to 10, Y from 0.1 to 10, and Z from 0.1 to 10.

9. The method of claim 1, wherein the carrier gas is inert relative to the adhesion promoter substance.

10. The method of claim 1, wherein nitrogen, oxygen, air, and/or a noble gas is used as the carrier gas.

11. A device for carrying out the method of claim 1, comprising a block, a carrier gas channel running through the block, and a mechanism for feeding the adhesion promoter substance into the carrier gas channel.

12. The device of claim 11, the mechanism comprising a mechanism for heating the block attached to the block.

13. The method of claim 6, wherein R¹ stands for a linear or branched, optionally cyclic alkylene group with 1 to 20 C atoms, optionally with aromatic moieties and optionally with one or more nitrogen atoms,
R² stands for a methyl group or an ethyl group, or an acyl group;
R³ stands for an alkyl group with 1 to 8 C atoms, in particular a methyl group,
X stands for H or an amino group,
X¹ stands for a functional group selected from the group consisting of NH, S, S₂, and S₄,
X² stands for a functional group selected from the group consisting of N and an isocyanurate group, and
a is 0.

14. The method of claim 1, wherein the adhesion promoter composition contains a mixture of:
A: N-(2-aminoethyl)-3-aminopropyltrimethoxysilane,
B: bis(3-trimethoxysilylpropyl)amine, and
C: 3-mercaptopropyltrimethoxysilane,
and the weight ratio of A:B:C is in particular X:Y:Z, with the value of X from 0.1 to 10, Y from 0.1 to 10, and Z from 0.1 to 10.
